(19) United States
(12) Patent Application Publication
(10) Pub. No.: US 2015/0315011 A1
(43) Pub. Date: Nov. 5, 2015

(54) MEMS STRUCTURE, ELECTRONIC APPARATUS, AND MOVING OBJECT

(71) Applicant: Seiko Epson Corporation, Tokyo (JP)

(72) Inventors: Shogo INABA, Shiojiri (JP); Akihiko EBINA, Fujimi (JP); Takuya KINUGAWA, Chino (JP)

(21) Appl. No.: 14/698,034

(22) Filed: Apr. 28, 2015

(30) Foreign Application Priority Data
May 1, 2014 (JP) 2014-094456

(51) Int. Cl. B81B 3/00; B81C 1/00

(52) U.S. Cl. CPC B81B 3/0013; B81B 3/0021; B81C 1/0015; B81B 2203/0118

(57) ABSTRACT

A MEMS structure includes: a substrate; a lower electrode disposed above the substrate; an upper electrode including a movable portion disposed facing and spaced from the lower electrode; and a projection projecting from a surface of the movable portion on a side facing the lower electrode, the projection being composed of a material different from that of the movable portion.

### BACKGROUND

1. Technical Field

The present invention relates to a MEMS structure, an electronic apparatus, and a moving object.

2. Related Art

MEMS structures (MEMS devices) manufactured using a MEMS (Micro Electro Mechanical System) technique are applied to various structures (e.g., vibrators, filters, sensors, motors, etc.) having a movable portion.

For example, a MEMS device disclosed in JP-A-2012-135819 includes a substrate and a movable structure, in which the movable structure includes a movable portion disposed spaced from the substrate, a fixed portion fixed to the substrate, and a support beam coupling the movable portion with the fixed portion. The MEMS device can calculate, based on a change in electrostatic capacitance between the substrate and the movable portion, acceleration or angular velocity applied to the MEMS device.

In the manufacture of the MEMS device, as disclosed in JP-A-2012-135819, for example, the movable structure is formed by etching one of silicon layers of an SOI substrate so as to conform to the shape of the movable structure, and then etching a silicon oxide film (sacrificial layer) of the SOI substrate. The movable structure in which a minute gap is formed between the movable structure and the substrate by etching the sacrificial layer is likely to stick to the substrate when, for example, drying a rinse liquid after etching.

In the MEMS device disclosed in JP-A-2012-135819, therefore, projections are provided on each of a surface of the substrate on the movable structure side and a surface of the movable structure on the substrate side.

In the MEMS device disclosed in JP-A-2012-135819, however, the projection for reducing the sticking is composed of the same material (specifically, silicon) as the substrate or the movable structure, and therefore, the providing of the projection may cause an unexpected change in characteristics, resulting in a problem of reduced design flexibility.

### SUMMARY

An advantage of some aspects of the invention is to provide a MEMS structure capable of reducing the sticking of a movable electrode to a fixed electrode while increasing design flexibility, and provide an electronic apparatus and a moving object each including the MEMS structure.

The advantage can be implemented as the following application examples.

### Application Example 1

A MEMS structure according to this application example of the invention includes: a substrate; a fixed electrode disposed above the substrate; a movable electrode including a movable portion disposed facing and spaced from the fixed electrode; and a projection projecting from at least one of a surface of the fixed electrode on a side facing the movable portion and a surface of the movable portion on a side facing the fixed electrode, the projection including a material different from that of the fixed electrode or the movable portion.

According to the MEMS structure, since the projection is composed of a material different from that of the fixed electrode or the movable portion, characteristics can be adjusted by appropriately selecting the material constituting the projection. Therefore, even when the projection is provided on the fixed electrode or the movable portion, a change in characteristics caused by providing the projection can be set to a desired one. Due to these facts, it is possible to reduce the sticking of the movable electrode to the fixed electrode while increasing design flexibility.

### Application Example 2

In the MEMS structure according to the application example of the invention, it is preferable that the projection includes a metal.

With this configuration, the conductivity of the projection can be made excellent, and the electrical characteristics of the fixed electrode or the movable portion can be made excellent. Moreover, the projection can be formed simply and highly accurately by deposition. While the fixed electrode and the movable electrode are generally formed using silicon, many metals have greater specific gravities than silicon. Therefore, the projection is composed of a metal, whereby the mass of a vibrating system including the movable portion is increased, and the movable portion can be downsized or the frequency of the vibrating system can be lowered.

### Application Example 3

In the MEMS structure according to the application example of the invention, it is preferable that the metal is tungsten.

Tungsten has an extremely high melting point. Therefore, even when an overcurrent flows through the projection due to a short circuit between the movable portion and the fixed electrode via the projection, the melting of the projection can be reduced. Moreover, since tungsten has an extremely high hardness, the projection is less deformable even when the projection contacts the movable portion or the fixed electrode, so that it is possible to reduce a change in characteristics caused by the deformation of the projection.

### Application Example 4

In the MEMS structure according to the application example of the invention, it is preferable that the MEMS structure further includes a metal portion penetrating the movable portion and including the metal, and that a portion of the metal portion projecting from the movable portion constitutes the projection.

With this configuration, the projection can be formed simply and highly accurately on the movable portion.

### Application Example 5

In the MEMS structure according to the application example of the invention, it is preferable that the melting point of a material constituting the projection is higher than the melting point of a material constituting at least one of the movable electrode and the fixed electrode.

With this configuration, even when an overcurrent flows through the projection due to a short circuit between the movable portion and the fixed electrode via the projection, the melting of the projection can be reduced.

### Application Example 6

In the MEMS structure according to the application example of the invention, it is preferable that the Young's modulus of a material constituting the projection is higher than the Young's modulus of a material constituting at least one of the movable electrode and the fixed electrode.

With this configuration, the projection is less deformable even when the projection contacts the movable portion or the fixed electrode, so that it is possible to reduce a change in characteristics caused by the deformation of the projection.

### Application Example 7

In the MEMS structure according to the application example of the invention, it is preferable that a material constituting the projection has resistance to an etchant containing hydrofluoric acid.

With this configuration, in the formation of a gap between the movable portion and the fixed electrode by etching the sacrificial layer composed of a silicon oxide film, etching of the projection can be reduced.

### Application Example 8

In the MEMS structure according to the application example of the invention, it is preferable that the number of the movable portions is more than one.

With this configuration, vibration leakage from the movable portions to the outside can be reduced.

### Application Example 9

In the MEMS structure according to the application example of the invention, it is preferable that the movable portion is supported in a cantilever fashion, and that the projection is disposed on a free end side of the movable portion.

With this configuration, it is possible to effectively reduce the sticking of the movable portion to the fixed electrode.

### Application Example 10

In the MEMS structure according to the application example of the invention, it is preferable that when viewed from a direction in which the fixed electrode and the movable portion are arranged in parallel, the projection is disposed in a region in which the fixed electrode and the movable portion overlap each other.

With this configuration, it is possible to effectively reduce the sticking of the movable portion to the fixed electrode while reducing, by suppressing the height of the projection, a change in vibration characteristics caused by providing the projection.

### Application Example 11

In the MEMS structure according to the application example of the invention, it is preferable that the MEMS structure is an electrostatically driven vibrator in which the movable portion is vibrated by generating a periodically changing electric field between the fixed electrode and the movable portion.

With this configuration, it is possible to provide an electrostatically driven vibrator capable of reducing the sticking of the movable electrode to the fixed electrode while increasing design flexibility.

### Application Example 12

A method of manufacturing a MEMS structure according to this application example of the invention includes: preparing a substrate; forming a fixed electrode forming film on the substrate; forming a sacrificial layer on the fixed electrode forming film; forming a movable electrode forming film on the sacrificial layer; forming, from a metal, a projection projecting from a surface of the movable electrode forming film on the fixed electrode forming film side; and etching the sacrificial layer.

With this configuration, it is possible to manufacture the MEMS structure capable of reducing the sticking of the movable electrode to the fixed electrode while increasing design flexibility.

### Application Example 13

An electronic apparatus according to this application example of the invention includes the MEMS structure according to the application example of the invention.

With this configuration, it is possible to provide the electronic apparatus including the MEMS structure capable of reducing the sticking of the movable electrode to the fixed electrode while increasing design flexibility.

### Application Example 14

A moving object according to this application example of the invention includes the MEMS structure according to the application example of the invention.

With this configuration, it is possible to provide the moving object including the MEMS structure capable of reducing the sticking of the movable electrode to the fixed electrode while increasing design flexibility.

### BRIEF DESCRIPTION OF THE DRAWINGS

The invention will be described with reference to the accompanying drawings, wherein like numbers reference like elements.

FIG. 1 is a cross-sectional view showing a MEMS structure according to a first embodiment of the invention.

FIGS. 2A and 2B show a vibrating element included in the MEMS structure shown in FIG. 1, in which FIG. 2A is a cross-sectional view, and FIG. 2B is a plan view.

FIGS. 3A to 3E show a manufacturing step (fixed electrode forming step) of the MEMS structure shown in FIG. 1.

FIGS. 4A to 4E show a manufacturing step (movable electrode forming step) of the MEMS structure shown in FIG. 1.

FIGS. 5A to 5C show a manufacturing step (cavity forming step) of the MEMS structure shown in FIG. 1.

FIGS. 6A and 6B show a vibrating element included in a MEMS structure according to a second embodiment of the invention, in which FIG. 6A is a cross-sectional view, and FIG. 6B is a plan view.

FIGS. 7A and 7B show a vibrating element included in a MEMS structure according to a third embodiment of the invention, in which FIG. 7A is a cross-sectional view, and FIG. 7B is a plan view.

FIG. 8 is a cross-sectional view showing a MEMS structure according to a fourth embodiment of the invention.

FIG. 9 is a perspective view showing a configuration of a mobile (or notebook) personal computer as a first example of an electronic apparatus according to the invention.

FIG. 10 is a perspective view showing a configuration of a mobile phone (including a PHS) as a second example of the electronic apparatus according to the invention.

FIG. 11 is a perspective view showing a configuration of a digital still camera as a third example of the electronic apparatus according to the invention.

FIG. 12 is a perspective view showing a configuration of an automobile as an example of a moving object according to the invention.

### DESCRIPTION OF EXEMPLARY EMBODIMENTS

Hereinafter, a MEMS structure, an electronic apparatus, and a moving object according to the invention will be described in detail based on embodiments shown in the accompanying drawings.

### First Embodiment

### 1. MEMS Structure

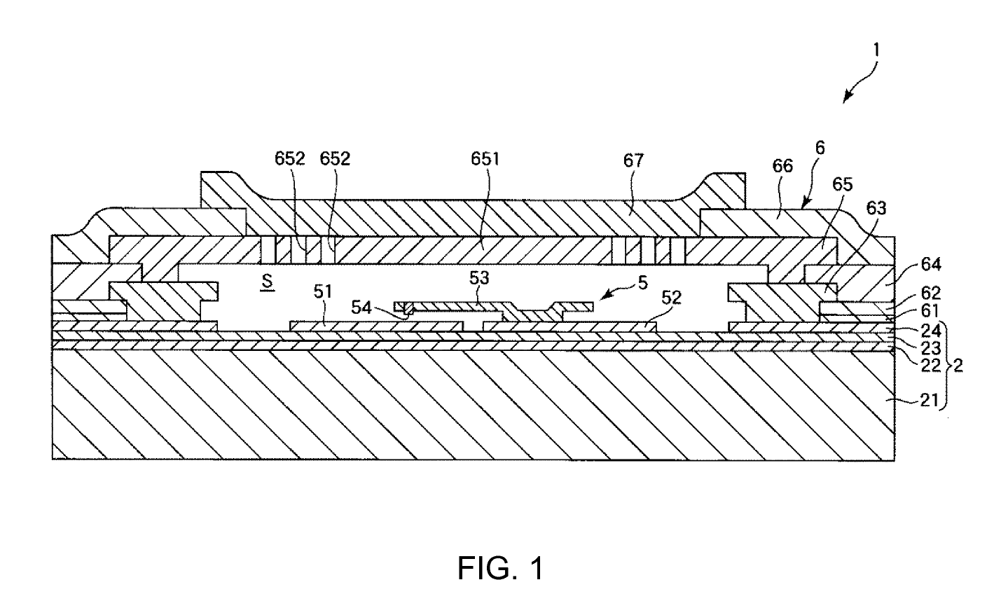

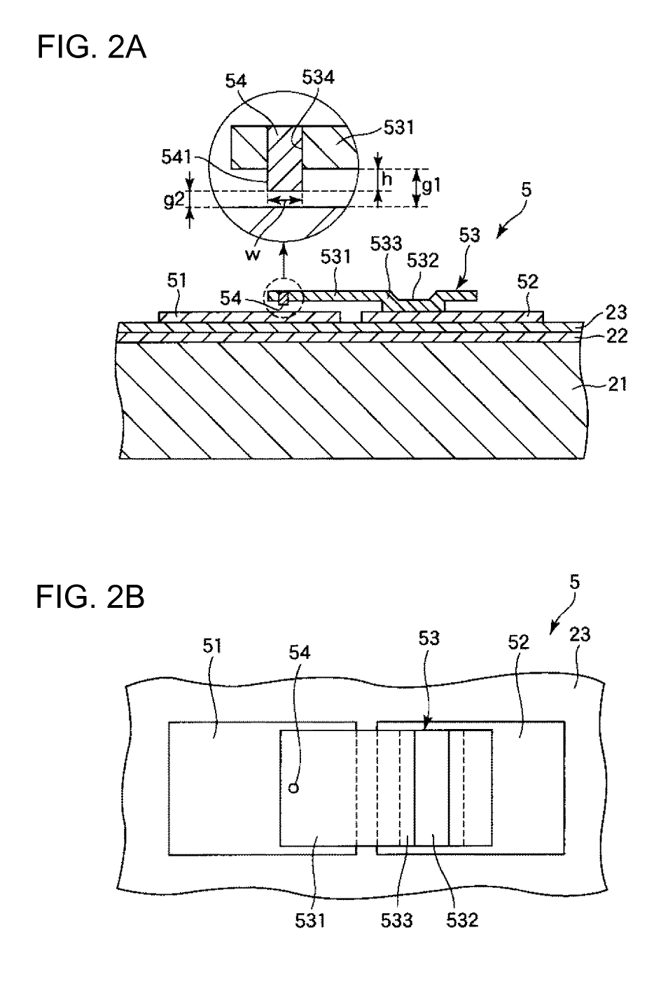

FIG. 1 is a cross-sectional view showing a MEMS structure according to a first embodiment of the invention. FIGS. 2A and 2B show a vibrating element included in the MEMS structure shown in FIG. 1, in which FIG. 2A is a cross-sectional view, and FIG. 2B is a plan view.

The MEMS structure 1 shown in FIG. 1 includes a substrate 2 (base), a vibrating element 5 disposed on the substrate 2, and a stacked structure 6 forming a cavity S that accommodates the vibrating element 5 relative to the substrate 2. These parts will be sequentially described below.

### Substrate 2

The substrate 2 includes a semiconductor substrate 21, an insulating film 22 provided on one of surfaces of the semiconductor substrate 21, an insulating film 23 provided on the insulating film 22, and a conductor layer 24 provided on the insulating film 23.

The semiconductor substrate 21 is composed of semiconductor such as silicon. The semiconductor substrate 21 is not limited to a substrate composed of a single material, such as a silicon substrate, and may be, for example, a substrate having a stacked structure, such as an SOI substrate.

The insulating film 22 is, for example, a silicon oxide film, and has an insulating property. The insulating film 23 is, for example, a silicon nitride film, and has an insulating property and resistance to an etchant containing hydrofluoric acid. Here, since the insulating film 22 (silicon oxide film) is present between the semiconductor substrate 21 (silicon substrate) and the insulating film 23 (silicon nitride film), the transfer of stress occurring in deposition of the insulating film 23 to the semiconductor substrate 21 can be mitigated with the insulating film 22. Moreover, the insulating film 22 can be used also as an element isolation film when a semiconductor circuit is formed on and above the semiconductor substrate 21. The insulating films 22 and 23 are not limited to the constituent material described above, and one of the insulating films 22 and 23 may be omitted as necessary.

The conductor layer 24 is configured by, for example, doping (diffusion or implantation) monocrystalline silicon, polycrystalline silicon (polysilicon), or amorphous silicon with an impurity such as phosphorus or boron, and has conductivity. Although not shown in the drawing, the conductor layer 24 is patterned so as to have a first portion that constitutes a wire electrically connected to the vibrating element 5, and a second portion that is spaced and electrically insulated from the first portion.

### Vibrating Element 5

As shown in FIGS. 2A and 2B, the vibrating element 5 includes a pair of lower electrodes 51 and 52 disposed on the insulating film 23 of the substrate 2 and an upper electrode 53 supported to the lower electrode 52.

The lower electrodes 51 and 52 each have a plate-like or sheet-like shape along the substrate 2, and are disposed spaced from each other. Although not shown in the drawings, the lower electrodes 51 and 52 are electrically connected to the above-described wire included in the conductor layer 24. Here, the lower electrode 51 constitutes a “fixed electrode”. The lower electrode 52 can be omitted. In this case, the upper electrode 53 is directly fixed to the insulating film 23.

The upper electrode 53 includes a plate-like or sheet-like movable portion 531 facing and spaced from the lower electrode 51, a fixed portion 532 fixed to the lower electrode 52, and a coupling portion 533 coupling the movable portion 531 with the fixed portion 532. The upper electrode 53 is electrically connected to the lower electrode 52. Here, the upper electrode 53 constitutes a “movable electrode”.

Each of the lower electrodes 51 and 52 and the upper electrode 53 is configured by doping (diffusion or implantation) monocrystalline silicon, polycrystalline silicon (polysilicon), or amorphous silicon with an impurity such as phosphorus or boron, and has conductivity.

The film thickness of each of the lower electrodes 51 and 52 is not particularly limited but can be set to, for example, from 0.1 μm to 1.0 μm. The film thickness of the upper electrode 53 is not particularly limited but can be set to, for example, from 0.1 μm to 1.0 μm.

The movable portion 531 supported in a cantilever fashion to the fixed portion 532 as described above is provided with a metal portion 54 penetrating the movable portion 531 in a thickness direction thereof at a portion on a free end side (on the side opposite to the fixed portion 532) of the movable portion 531. The metal portion 54 includes a projection 541 projecting from a surface of the movable portion 531 on the lower electrode 51 side. The projection 541 has a function of reducing the sticking of the movable portion 531 to the lower electrode 51. The metal portion 54 and the projection 541 will be described in detail later.

### Stacked Structure 6

The stacked structure 6 is formed so as to define the cavity S accommodating the vibrating element 5. The stacked structure 6 includes: an inter-layer insulating film 61 formed on the substrate 2 so as to surround the vibrating element 5 in a plan view; an inter-layer insulating film 62 formed on the inter-layer insulating film 61; a wiring layer 63 formed on the inter-layer insulating film 62; an inter-layer insulating film 64 formed on the wiring layer 63 and the inter-layer insulating film 62; a wiring layer 65 formed on the inter-layer insulating film 64 and including a covering layer 651 in which a plurality of fine pores 652 (opening holes) are formed; a surface protective film 66 formed on the wiring layer 65 and the inter-layer insulating film 64; and a sealing layer 67 provided on the covering layer 651.

Each of the inter-layer insulating films 61, 62, and 64 is, for example, a silicon oxide film. Each of the wiring layers 63 and 65 and the sealing layer 67 is composed of a metal such as aluminum. The surface protective film 66 is, for example, a silicon nitride film.

On and above the semiconductor substrate 21, a semiconductor circuit may be fabricated other than the configurations described above. The semiconductor circuit includes active elements, such as MOS transistors, and other circuit elements formed as necessary, such as capacitors, inductors, resistors, diodes, and wires (including the wire connected to the lower electrode 51, the wire connected to the upper electrode 53, and the wiring layers 63 and 65). Although not shown in the drawings, the above-described wire electrically connected to the vibrating element 5 is disposed across the inside and outside of the cavity S between the wiring layer 63 and the insulating film 23, and the wiring layer 63 is formed so as to be spaced from the wire.

The cavity S defined by the substrate 2 and the stacked structure 6 functions as a containing portion that contains the vibrating element 5. Moreover, the cavity S is a hermetically sealed space. In the embodiment, the cavity S is in a vacuum state (300 Pa or less). With this configuration, vibration characteristics of the vibrating element 5 can be made excellent. However, the cavity S may not be in the vacuum state, and may be in an atmospheric pressure, a reduced-pressure state where the air pressure is lower than the atmospheric pressure, or a pressurized state where the air pressure is higher than the atmospheric pressure. Moreover, an inert gas such as nitrogen gas or noble gas may be sealed in the cavity S.

The configuration of the MEMS structure 1 has been briefly described above.

In the MEMS structure 1 configured as described above, with the application of a periodically changing voltage between the lower electrode 51 and the upper electrode 53, the movable portion 531 flexurally vibrates while being displaced alternately in directions toward and away from the lower electrode 51. As described above, the MEMS structure 1 can be used as an electrostatically driven vibrator in which the movable portion 531 is vibrated by generating a periodically changing electric field between the lower electrode 51 and the movable portion 531.

The MEMS structure 1 can be used as an oscillator to extract a signal at a predetermined frequency by, for example, combining with an oscillation circuit (driver circuit). The oscillation circuit can be provided as a semiconductor circuit on the substrate 2. Moreover, the MEMS structure 1 can also be applied to various types of sensors such as gyro sensors, pressure sensors, acceleration sensors, and inclination sensors.

### Metal Portion and Projection

Here, the metal portion 54 provided in the upper electrode 53 and including the projection 541 will be described.

As described above, the movable portion 531 supported in a cantilever fashion to the fixed portion 532 is provided with the metal portion 54 penetrating the movable portion 531 in the thickness direction thereof at a portion on the free end side (on the side opposite to the fixed portion 532). As shown in FIG. 2A, the metal portion 54 is inserted into a through-hole 534 formed in the movable portion 531. The metal portion 54 includes the projection 541 projecting from the surface of the movable portion 531 on the lower electrode 51 side. In the embodiment, one metal portion 54 is provided at the central portion of the movable portion 531 in a width direction thereof (a direction vertical to a direction in which the fixed end and the free end are arranged in parallel in the plan view). The support in a cantilever fashion as used herein means that one end is free while the other end is fixed.

In the embodiment, the transverse cross-sectional shape (plan-view shape) of the metal portion 54 and the projection 541 is circular. The metal portion 54 is provided at the central portion of the movable portion 531 in the width direction thereof. The transverse cross-sectional shape of the metal portion 54 and the projection 541 is not limited to be circular but may be, for example, elliptical, or polygonal such as quadrilateral. The number of the metal portions 54 is one in the embodiment, but the number of the metal portions 54 may be more than one. In this case, a plurality of metal portions 54 may be arranged in parallel in the width direction of the movable portion 531, or may be arranged in parallel along the direction in which the fixed and free ends of the movable portion 531 are arranged in parallel. The metal portions 54 may be arranged regularly or irregularly. Moreover, a tip portion of the projection 541 has a flat tip surface in the illustration, but the tip portion is not limited to this, and may be, for example, rounded or sharpened.

The projection 541 projects from the surface of the movable portion 531 disposed facing and spaced from the lower electrode 51 where the surface is located on the side facing the lower electrode 51, and therefore, it is possible to reduce the sticking of the movable portion 531 to the lower electrode 51. Particularly, since the projection 541 is composed of a different material (metal in the embodiment) from the movable portion 531, characteristics can be adjusted by appropriately selecting the material constituting the projection 541 (the metal portion 54). Therefore, even when the projection 541 is provided on the movable portion 531, a change in characteristics caused by providing the projection 541 can be set to a desired one. From these facts, it is possible to reduce the sticking of the upper electrode 53 to the lower electrode 51 while increasing design flexibility.

Here, since the projection 541 is disposed on the free end side of the movable portion 531 that is supported in a cantilever fashion, it is possible to effectively reduce the sticking of the movable portion 531 to the lower electrode 51.

Moreover, when viewed from the direction in which the lower electrode 51 and the movable portion 531 are arranged in parallel (i.e., in the plan view), the projection 541 is disposed in a region in which the lower electrode 51 and the movable portion 531 overlap each other. With this configuration, it is possible to effectively reduce the sticking of the movable portion 531 to the lower electrode 51 while reducing, by suppressing the height of the projection 541, a change in vibration characteristics caused by providing the projection 541.

Moreover, the portion of the metal portion 54 projecting from the movable portion 531 that the metal portion 54 penetrates constitutes the projection 541, and therefore, the projection 541 can be formed simply and highly accurately on the movable portion 531 using a process similar to a semiconductor manufacturing process as will be described in detail later.

Moreover, since the projection 541 is composed of a metal, the conductivity of the projection 541 can be made excellent, and the electrical characteristics of the movable portion 531 can be made excellent. Moreover, as will be described in detail later, the projection 541 can be formed simply and highly accurately by deposition. While each of the lower electrodes 51 and 52 and the upper electrode 53 is generally formed using silicon, many metals have greater specific gravities than silicon. Therefore, the projection 541 is composed of a metal, whereby the mass of a vibrating system including the movable portion 531 is increased, and the movable portion 531 can be downsized or the frequency of the vibrating system can be lowered.

Here, the metal constituting the metal portion 54 is appropriately selected depending on the design of the movable portion 531 without particular limitations as long as the material can allow the projection 541 to reduce the sticking of the movable portion 531 to the lower electrode 51. Although many kinds of metals can be used, it is preferable to use a material that can be deposited in a semiconductor process.

Moreover, it is preferable that the melting point of the material constituting the projection 541 is higher than the melting point of the material (i.e., silicon) constituting at least one of the lower electrode 51 and the upper electrode 53. With this configuration, even when an overcurrent flows through the projection 541 due to a short circuit between the movable portion 531 and the lower electrode 51 via the projection 541, the melting of the projection 541 can be reduced.

Moreover, it is preferable that the Young's modulus of the material constituting the projection 541 is higher than the Young's modulus of the material constituting the lower electrode 51. With this configuration, the projection 541 is less deformable even when the projection 541 contacts the lower electrode 51, so that it is possible to reduce a change in characteristics (e.g., a change in the vibration characteristics of the movable portion 531) caused by the deformation of the projection 541. When a projection is provided on a surface of the lower electrode 51 on the movable portion 531 side, the Young's modulus of the constituent material of the projection is made higher than the Young's modulus of the constituent material of the movable portion 531.

Moreover, it is preferable that the material constituting the projection 541 has resistance to an etchant containing hydrofluoric acid. With this configuration, when a gap is formed between the movable portion 531 and the lower electrode 51 by etching a sacrificial layer composed of a silicon oxide film as will be described in detail later, the etching of the projection 541 can be reduced.

From the viewpoint of the constituent material of the projection 541 described above, it is preferable to use tungsten or a tungsten alloy as the metal constituting the metal portion 54. Tungsten has an extremely high melting point. Therefore, even when an overcurrent flows through the projection 541 due to a short circuit between the movable portion 531 and the lower electrode 51 via the projection 541, the melting of the projection 541 can be reduced. Moreover, since tungsten has an extremely high hardness, the projection 541 is less deformable even when the projection 541 contacts the lower electrode 51, so that it is possible to reduce a change in characteristics caused by the deformation of the projection 541.

Moreover, a height h (projection amount) of the projection 541 varies depending on a distance g1 between the movable portion 531 and the lower electrode 51, and is not particularly limited as long as the sticking of the movable portion 531 to the lower electrode 51 can be reduced. For example, the height h is about from 0.1 μm to 10 μm.

Moreover, a width W of the projection 541 is not particularly limited as long as the sticking of the movable portion 531 to the lower electrode 51 can be reduced, but is, for example, about from 0.1 μm to 10 μm.

Moreover, a distance g2 between the tip of the projection 541 and the lower electrode 51 is set to such an extent that the projection 541 does not contact the lower electrode 51 when the vibrating element 5 is driven as described above.

### Method of Manufacturing MEMS Structure

Next, a method of manufacturing the MEMS structure 1 will be briefly described.

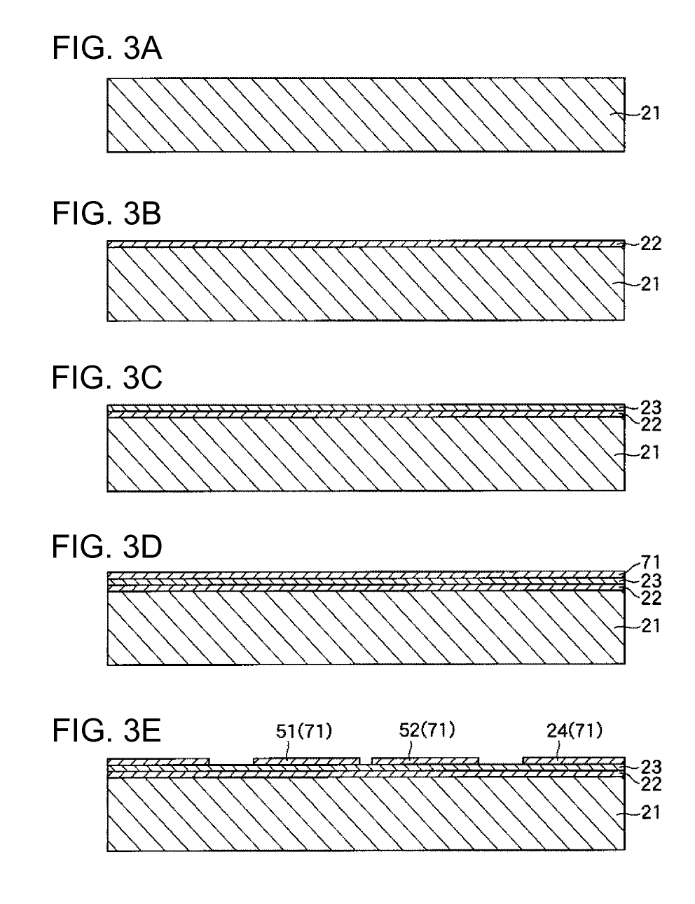

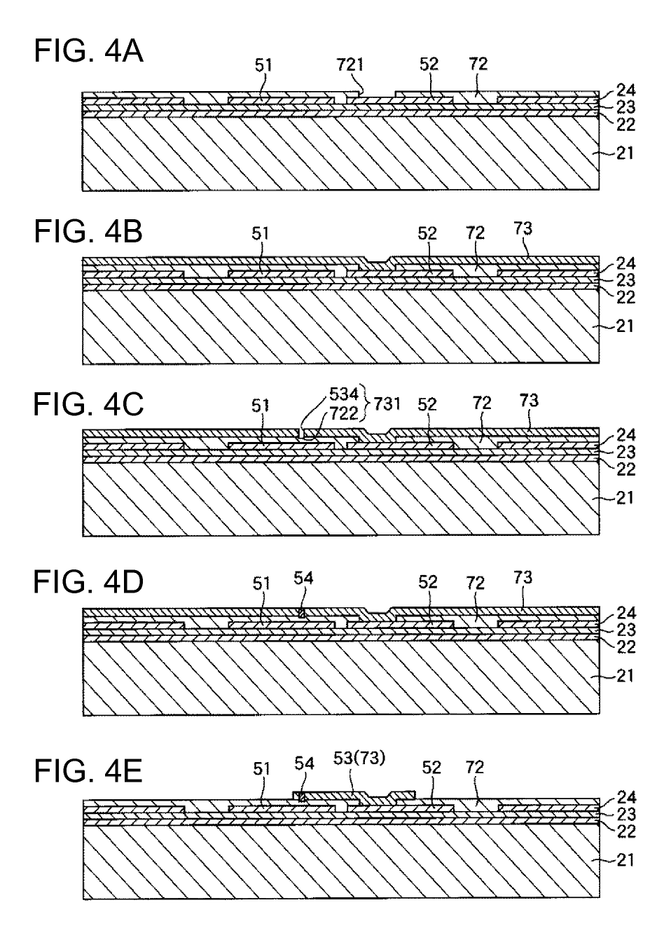

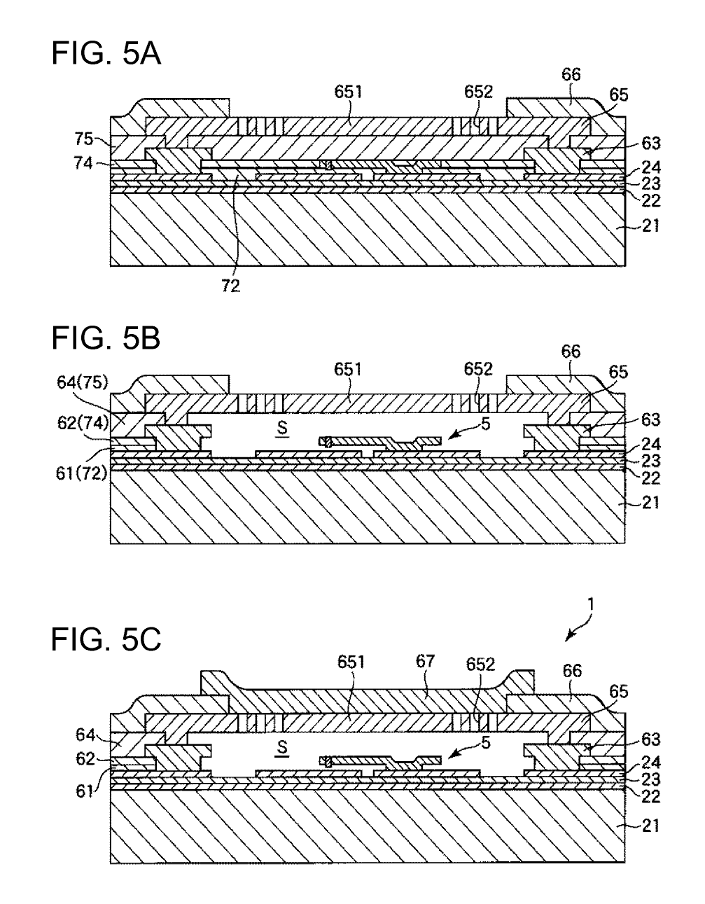

FIGS. 3A to 3E show a manufacturing step (fixed electrode forming step) of the MEMS structure shown in FIG. 1; FIGS. 4A to 4E show a manufacturing step (movable electrode forming step) of the MEMS structure shown in FIG. 1; and FIGS. 5A to 5C show a manufacturing step (cavity forming step) of the MEMS structure shown in FIG. 1. The manufacturing method will be described below based on the drawings.

### Vibrating Element Forming Step

### Step of Preparing Substrate

First, as shown in FIG. 3A, the semiconductor substrate 21 (silicon substrate) is prepared.

When a semiconductor circuit is formed on and above the semiconductor substrate 21, a source and a drain of a MOS transistor of the semiconductor circuit are formed by ion doping at a portion in which the insulating film 22 and the insulating film 23 are not formed in an upper surface of the semiconductor substrate 21.

Next, as shown in FIG. 3B, the insulating film 22 (silicon oxide film) is formed on the upper surface of the semiconductor substrate 21.

A forming method of the insulating film 22 (silicon oxide film) is not particularly limited, and, for example, a thermal oxidation method, a sputtering method, a CVD method, or the like can be used. The insulating film 22 may be patterned as necessary, and when, for example, a semiconductor circuit is formed on and above the upper surface of the semiconductor substrate 21, the insulating film 22 is patterned so as to expose a portion of the upper surface of the semiconductor substrate 21.

Thereafter, as shown in FIG. 3C, the insulating film 23 (silicon nitride film) is formed on the insulating film 22.

A forming method of the insulating film 23 (silicon nitride film) is not particularly limited, and, for example, a sputtering method, a CVD method, or the like can be used. The insulating film 23 may be patterned as necessary, and when, for example, a semiconductor circuit is formed on and above the upper surface of the semiconductor substrate 21, the insulating film 23 is patterned so as to expose a portion of the upper surface of the semiconductor substrate 21.

### Step of Forming Fixed Electrode Forming Film

Next, as shown in FIG. 3D, a conductor film 71 (fixed electrode forming film) for forming the conductor layer 24 and the lower electrodes 51 and 52 is formed on the insulating film 23.

Specifically, for example, a silicon film composed of polycrystalline silicon or amorphous silicon is formed on the insulating film 23 by a sputtering method, a CVD method, or the like, and thereafter, the silicon film is doped with an impurity such as phosphorus to thereby form the conductor film 71. Depending on the configuration of the insulating film 23, an epitaxially grown silicon film may be doped with an impurity such as phosphorus to thereby form the conductor film 71.

Next, the conductor film 71 is patterned to form the conductor layer 24 and the lower electrodes 51 and 52 as shown in FIG. 3E.

Specifically, for example, a photoresist is applied on the conductor film 71 and patterned into the shapes (plan-view shapes) of the conductor layer 24 and the lower electrodes 51 and 52 to form a photoresist film. Then, the conductor film 71 is etched using the photoresist film as a mask, and thereafter, the photoresist film is removed. With this configuration, the conductor layer 24 and the lower electrodes 51 and 52 are formed.

When a semiconductor circuit is formed on and above the upper surface of the semiconductor substrate 21, for example, the conductor film 71 is patterned simultaneously with the patterning of the lower electrodes 51 and 52 or the like to form a gate electrode of a MOS transistor of the semiconductor circuit.

### Step of Forming Sacrificial Layer

Next, as shown in FIG. 4A, a sacrificial layer 72 is formed on the lower electrode 51. In the embodiment, the sacrificial layer 72 is formed over the entire region other than a portion (portion at which the fixed portion 532 is formed) on the lower electrode 52. In the sacrificial layer 72, an opening 721 is formed corresponding to the portion at which the fixed portion 532 is formed.

In the embodiment, the sacrificial layer 72 is a silicon oxide film, a portion of which is removed in a later-described step and the remaining portion of which serves as the inter-layer insulating film 61. When the inter-layer insulating film 61 is omitted, the sacrificial layer 72 may be formed so as to cover only the lower electrode 51. Moreover, the sacrificial layer 72 may be composed of PSG (phosphorus-doped glass) or the like.

A forming method of the sacrificial layer 72 is not particularly limited, and, for example, a sputtering method, a CVD method, or the like can be used.

### Step of Forming Movable Electrode Forming Film

Next, as shown in FIG. 4B, a conductor film 73 (movable electrode forming film) for forming the upper electrode 53 is formed in the opening 721 and on the sacrificial layer 72.

Specifically, for example, polycrystalline silicon or amorphous silicon is deposited in the opening 721 and on the sacrificial layer 72 by a sputtering method, a CVD method, or the like to forma silicon film, and thereafter, the silicon film is doped with an impurity such as phosphorus to thereby form the conductor film 73. Depending on the configuration of the sacrificial layer 72, an epitaxially grown silicon film may be doped with an impurity such as phosphorus to thereby form the conductor film 73. Moreover, the silicon film may be planarized by etch back, CMP (chemical mechanical polishing), or the like.

Step of Forming Projection from Metal

Next, as shown in FIG. 4C, the through-hole 534 is formed in the conductor film 73. At this time, a recess 722 having a shape corresponding to the projection 541 is formed in the sacrificial layer 72 so as to be contiguous to the through-hole 534. That is, in a stacked body formed of the conductor film 73 and the sacrificial layer 72, a recess 731 composed of the through-hole 534 and the recess 722 is formed so as to have a shape corresponding to the metal portion 54.

A forming method of the recess 731 is not particularly limited, but, for example, dry etching can be used. With the use of dry etching, the minute recess 722 can be simply formed by making use of overetching in the formation of the through-hole 534. In dry etching, a resist film using photolithography can be used as a mask.

Next, the metal portion 54 is formed by filling the recess 731 with a metal as shown in FIG. 4D.

Specifically, for example, a metal such as tungsten is deposited in the recess 731 and on the conductor film 73 by a sputtering method, a CVD method, or the like to form a metal film, and thereafter, an unwanted portion of the metal film other than that in the recess 731 is removed by etch back, CMP, or the like to leave the metal only in the recess 731. With this configuration, the metal portion 54 including the projection 541 that projects from a surface of the conductor film 73 on the conductor film 71 side can be formed from a metal. In the formation of the metal film, a metal may be deposited a plurality of times. In this case, in the first or second deposition of the metal, a glue layer may be formed using titanium, titanium nitride, or the like as a metal.

Next, as shown in FIG. 4E, the conductor film 73 is patterned to form the upper electrode 53.

Specifically, for example, a photoresist is applied on the conductor film 73 and patterned into the shape (plan-view shape) of the upper electrode 53 to form a photoresist film. Then, the conductor film 73 is etched using the photoresist film as a mask, and thereafter, the photoresist film is removed. With this configuration, the upper electrode 53 is formed.

In the manner described above, the vibrating element 5 including the lower electrodes 51 and 52 and the upper electrode 53 is formed.

### Cavity Forming Step

As shown in FIG. 5A, inter-layer insulating films 74 and 75, the wiring layers 63 and 65, and the surface protective film 66 are formed on the upper side of the upper electrode 53 and the sacrificial layer 72.

Specifically, for example, a silicon oxide film is formed on the upper electrode 53 and the sacrificial layer 72 by a sputtering method, a CVD method, or the like, and the silicon oxide film is patterned by etching, to thereby form the inter-layer insulating film 74 in which a through-hole having a shape corresponding to the wiring layer 63 is formed. Then, a film made of aluminum is formed on the inter-layer insulating film 74 by a sputtering method, a CVD method, or the like so as to fill the through-hole of the inter-layer insulating film 74, and the film is patterned (an unwanted portion is removed) by etching, to thereby form the wiring layer 63.

Thereafter, the inter-layer insulating film 75 is formed in the same manner as the inter-layer insulating film 74, and then, the wiring layer 65 is formed in the same manner as the wiring layer 63. After forming the wiring layer 65, the surface protective film 66 such as a silicon oxide film, a silicon nitride film, a polyimide film, or epoxy resin is formed by a sputtering method, a CVD method, or the like.

The stacked structure of the inter-layer insulating film and the wiring layer is formed by a common CMOS process, and the number of stacked layers is appropriately set as necessary. That is, more wiring layers may be stacked as necessary via an inter-layer insulating film. Moreover, when a semiconductor circuit is formed on and above the upper surface of the semiconductor substrate 21, a wiring layer electrically connected to the gate electrode or the like of the MOS transistor of the semiconductor circuit is formed simultaneously with, for example, the formation of the wiring layers 63 and 65.

### Step of Etching Sacrificial Layer

Next, as shown in FIG. 5B, portions of the sacrificial layer 72 and the inter-layer insulating films 74 and 75 are removed, whereby the cavity S and the inter-layer insulating films 61, 62, and 64 are formed.

Specifically, the sacrificial layer 72 and the inter-layer insulating films 74 and 75 that are located around the vibrating element 5 and between the lower electrode 51 and the movable portion 531 are removed by etching through the plurality of fine pores 652 formed in the covering layer 651. With this configuration, the cavity S in which the vibrating element 5 is accommodated is formed, and at the same time, a gap is formed between the lower electrode 51 and the movable portion 531, so that the vibrating element 5 is brought into a state where the vibrating element 5 can be driven.

Here, the removal (release step) of the inter-layer insulating films 74 and 75 and the sacrificial layer 72 can be carried out by, for example, wet etching in which hydrofluoric acid, buffered hydrofluoric acid, or the like is supplied as an etchant through the plurality of fine pores 652, or dry etching in which hydrofluoric acid gas or the like is supplied as an etching gas through the plurality of fine pores 652. At this time, the insulating film 23 and the wiring layers 63 and 65 have resistance to the etching implemented in the release step, and function as so-called etching stop layers. Before etching, a protective film may be formed as necessary from a photoresist or the like on an outer surface of a structure including an etching target portion.

Next, as shown in FIG. 5C, the sealing layer 67 is formed on the covering layer 651.

Specifically, for example, the sealing layer 67 composed of a silicon oxide film, a silicon nitride film, a metal film such as Al, Cu, W, Ti, or TiN, or the like is formed by a sputtering method, a CVD method, or the like to seal the fine pores 652.

Through the steps described above, the MEMS structure 1 can be manufactured.

The method of manufacturing the MEMS structure 1 described above includes: the step of preparing the semiconductor substrate 21; the step of forming the conductor film 71 (fixed electrode forming film) on the semiconductor substrate 21; the step of forming the sacrificial layer 72 on the conductor film 71; the step of forming the conductor film 73 (movable electrode forming film) on the sacrificial layer 72; the step of forming, from a metal, the projection 541 projecting from the surface of the conductor film 73 on the conductor film. 71 side; and the step of etching the sacrificial layer 72. With this configuration, it is possible to manufacture the MEMS structure 1 capable of reducing the sticking of the upper electrode 53 to the lower electrode 51 while increasing design flexibility.

### Second Embodiment

Next, a second embodiment of the invention will be described.

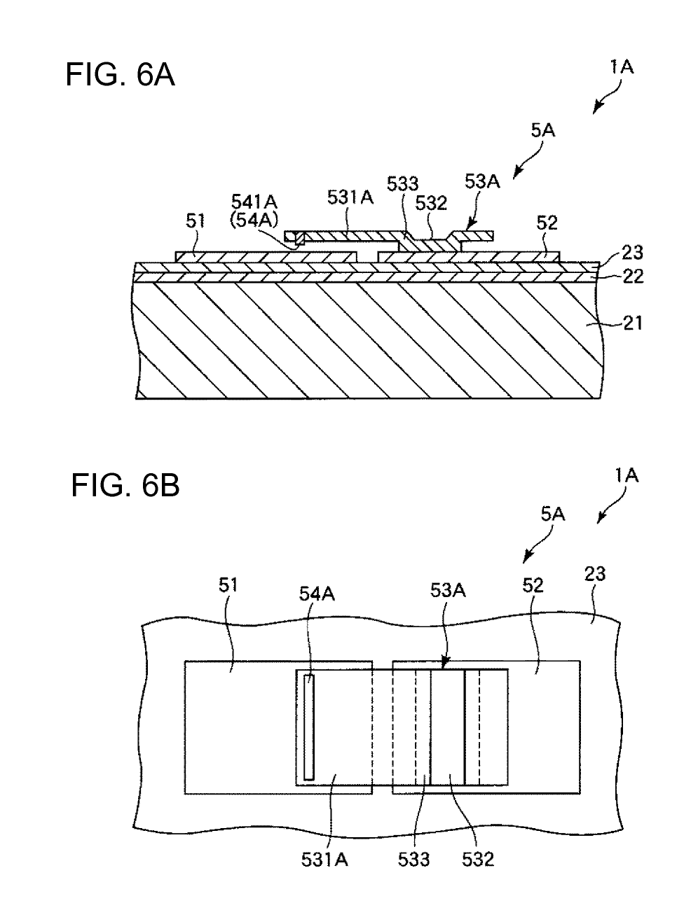

FIGS. 6A and 6B show a vibrating element included in a MEMS structure according to the second embodiment of the invention, in which FIG. 6A is a cross-sectional view, and FIG. 6B is a plan view.

Hereinafter, the second embodiment of the invention will be described, in which differences from the embodiment described above are mainly described, and similar matters are not described.

The second embodiment is similar to the first embodiment, except that the shape of the metal portion and the projection provided in the movable electrode is different.

The MEMS structure 1A shown in FIGS. 6A and 6B includes a vibrating element 5A. The vibrating element 5A includes the pair of lower electrodes 51 and 52 and an upper electrode 53A supported to the lower electrode 52. The upper electrode 53A (movable electrode) includes a movable portion 531A facing and spaced from the lower electrode 51, the fixed portion 532 provided on the lower electrode 52, and the coupling portion 533 coupling the movable portion 531A with the fixed portion 532.

As shown in FIG. 6A, the movable portion 531A is provided with a metal portion 54A penetrating the movable portion 531A in a thickness direction thereof at a portion on a free end side thereof. The metal portion 54A includes a projection 541A projecting from a surface of the movable portion 531A on the lower electrode 51 side. In the embodiment, as shown in FIG. 6B, the metal portion 54A and the projection 541A have a shape extending along the width direction of the movable portion 531A. The metal portion 54A may include a plurality of projections arranged in parallel in an extending direction of the metal portion 54A.

Even with the projection 541A, it is possible to reduce the sticking of the movable portion 531A to the lower electrode 51. Moreover, since the metal portion 54A extends along the width direction of the movable portion 531A, the second embodiment has a great effect of reinforcing the movable portion 531A with the metal portion 54A or lowering the resonant frequency of a vibrating system including the movable portion 531A.

### Third Embodiment

Next, a third embodiment of the invention will be described.

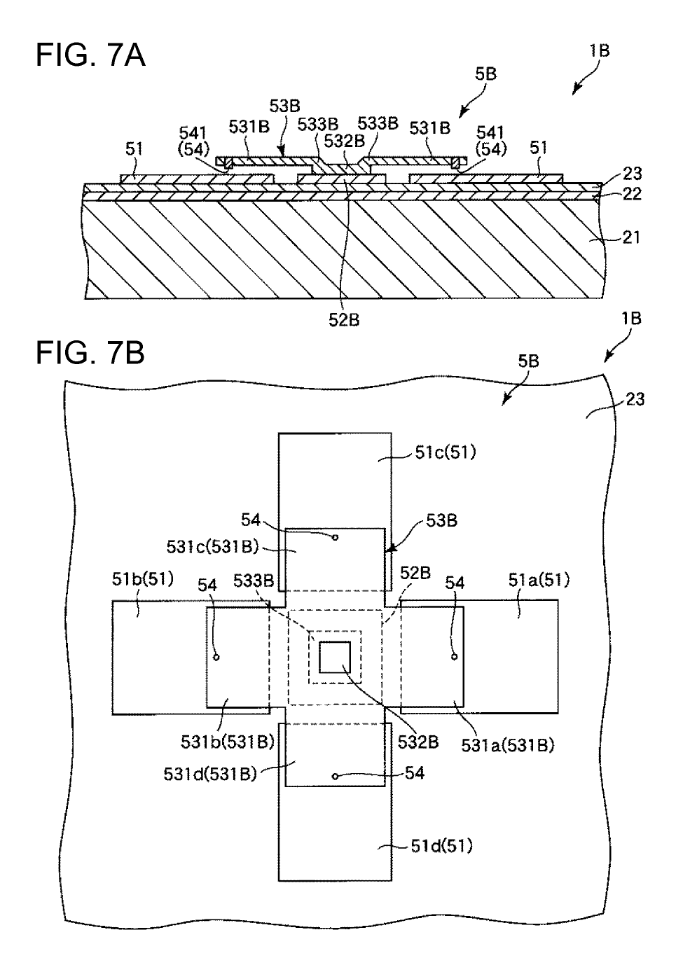

FIGS. 7A and 7B show a vibrating element included in a MEMS structure according to the third embodiment of the invention, in which FIG. 7A is a cross-sectional view, and FIG. 7B is a plan view.

Hereinafter, the third embodiment of the invention will be described, in which differences from the embodiments described above are mainly described, and similar matters are not described.

The third embodiment is similar to the first embodiment, except that the numbers of movable electrodes and fixed electrodes are different.

The MEMS structure 1B shown in FIGS. 7A and 7B includes a vibrating element 5B. The vibrating element 5B includes four lower electrodes 51, a lower electrode 52B, and an upper electrode 53B supported to the lower electrode 52B.

The four lower electrodes 51 (fixed electrodes) include two lower electrodes 51a and 51b arranged in parallel, with the lower electrode 52B interposed therebetween, along a first direction (the left-and-right direction in FIG. 7B) in the plan view, and two lower electrodes 51c and 51d arranged in parallel, with the lower electrode 52B interposed therebetween, along a second direction (the up-and-down direction in FIG. 7B) orthogonal to the first direction. Moreover, each of the four lower electrodes 51 is disposed spaced from the lower electrode 52B in the plan view.

The two lower electrodes 51a and 51b are configured such that the lower electrodes are electrically connected to each other via a wire (not shown) to be at the same potential. Similarly, the two lower electrodes 51c and 51d are configured such that the lower electrodes are electrically connected to each other via a wire (not shown) to be at the same potential.

The upper electrode 53B (movable electrode) includes four movable portions 531B, a fixed portion 532B fixed to the lower electrode 52B, and a coupling portion 533B coupling the movable portions 531B with the fixed portion 532B.

The four movable portions 531B are provided corresponding to the four lower electrodes 51. Each of the movable portions 531B faces and is spaced from the corresponding lower electrode 51. That is, the four movable portions 531B include two movable portions 531a and 531b arranged in parallel, with the fixed portion 532B interposed therebetween, along the first direction (the left-and-right direction in FIG. 7B), and two movable portions 531c and 531d arranged in parallel, with the fixed portion 532B interposed therebetween, along the second direction (the up-and-down direction in FIG. 7B) orthogonal to the first direction.

Each of the movable portions 531B of the upper electrode 53B is provided with the metal portion 54 penetrating the movable portion 531B in a thickness direction thereof at a portion on a free end side (on the side opposite to the fixed portion 532B) thereof. The metal portion 54 includes the projection 541 projecting from a surface of the movable portion 531B on the lower electrode 51 side.

In the MEMS structure 1B configured as described above, a periodically changing first voltage (alternating voltage) is applied between the lower electrodes 51a and 51b and the upper electrode 53B, and at the same time, a second voltage similar to the first voltage except that the phase is shifted by 180° is applied between the lower electrodes 51c and 51d and the upper electrode 53B.

Then, the movable portions 531a and 531b flexurally vibrate while being displaced alternately in directions toward and away from the lower electrodes 51a and 51b, and at the same time, the movable portions 531c and 531d flexurally vibrate, in opposite phase to the movable portions 531a and 531b, while being displaced alternately in directions toward and away from the lower electrodes 51c and 51d. That is, when the movable portions 531a and 531b are displaced in the direction toward the lower electrodes 51a and 51b, the movable portions 531c and 531d are displaced in the direction away from the lower electrodes 51c and 51d; while when the movable portions 531a and 531b are displaced in the direction away from the lower electrodes 51a and 51b, the movable portions 531c and 531d are displaced in the direction toward the lower electrodes 51c and 51d.

By vibrating the movable portions 531a and 531b and the movable portions 531c and 531d in opposite phase as described above, vibrations transmitted from the movable portions 531a and 531b to the fixed portion 532B and vibrations transmitted from the movable portions 531c and 531d to the fixed portion 532B can be canceled out each other. As a result, leaking of these vibrations to the outside via the fixed portion 532B, so-called vibration leakage, can be reduced, so that vibration efficiency of the MEMS structure 1B can be increased. As described above, since the number of movable portions 531B is more than one in the MEMS structure 1B, vibration leakage from the movable portions 531B to the outside can be reduced.

### Fourth Embodiment

Next, a fourth embodiment of the invention will be described.

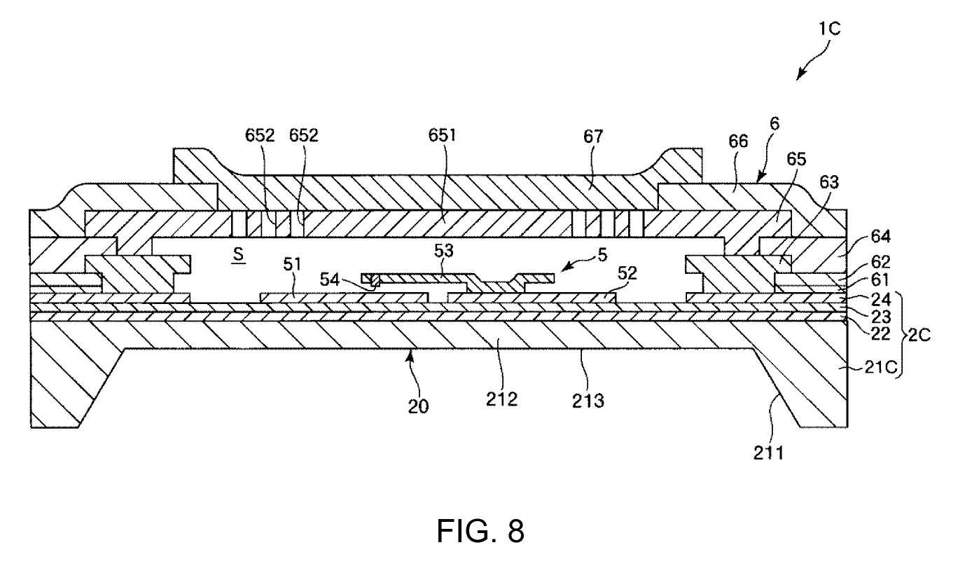

FIG. 8 is a cross-sectional view showing a MEMS structure according to the fourth embodiment of the invention.

Hereinafter, the fourth embodiment of the invention will be described, in which differences from the embodiments described above are mainly described, and similar matters are not described.

The fourth embodiment is similar to the first embodiment, except that the fourth embodiment includes a diaphragm portion.

The MEMS structure 1C shown in FIG. 8 is configured to be able to detect pressure. The MEMS structure 1C includes a substrate 2C including a diaphragm portion 20, instead of the substrate 2 in the MEMS structure 1 of the first embodiment.

The substrate 2C includes a semiconductor substrate 21C, the insulating film 22 provided on one of surfaces of the semiconductor substrate 21C, the insulating film 23 provided on the insulating film 22, and the conductor layer 24 provided on the insulating film 23.

The substrate 2C is provided with the diaphragm portion 20, which is thinner than the peripheral portion and deflected and deformed under pressure. The diaphragm portion 20 is formed by providing a bottomed recess 211 in a lower surface of the semiconductor substrate 21C. A lower surface of the diaphragm portion 20 is a pressure receiving surface 213. The recess 211 can be formed by etching.

In the substrate 2C of the embodiment, the recess 211 does not penetrate the semiconductor substrate 21C, and the diaphragm portion 20 is composed of three layers of a thin portion 212 of the semiconductor substrate 21C, the insulating film 22, and the insulating film 23.

The vibrating element 5 is provided on a surface of the diaphragm portion 20 on the side opposite to the pressure receiving surface 213. In the embodiment, the vibrating element 5 is disposed at the central portion of the diaphragm portion 20 in the plan view.

The cavity S in which the vibrating element 5 is accommodated functions as a pressure reference chamber serving to provide a reference value of the pressure detected by the MEMS structure 1C. By bringing the cavity S into the vacuum state, the MEMS structure 1C can be used as an “absolute pressure sensor” that detects pressure with the vacuum state as a reference, so that the convenience of the MEMS structure is improved.

In the MEMS structure 1C configured as described above, when pressure is applied to the pressure receiving surface 213, the diaphragm portion 20 is deflected and deformed toward the cavity S side. With the deformation, the gap (spaced distance) between the movable portion 531 of the upper electrode 53 and the lower electrode 51 changes.

When the gap between the movable portion 531 of the upper electrode 53 and the lower electrode 51 changes, the resonant frequency of a vibrating system composed of the lower electrode 51 and the upper electrode 53 changes. Therefore, based on the change in resonant frequency, the magnitude of the pressure (absolute pressure) received by the pressure receiving surface 213 can be obtained.

### 2. Electronic Apparatus

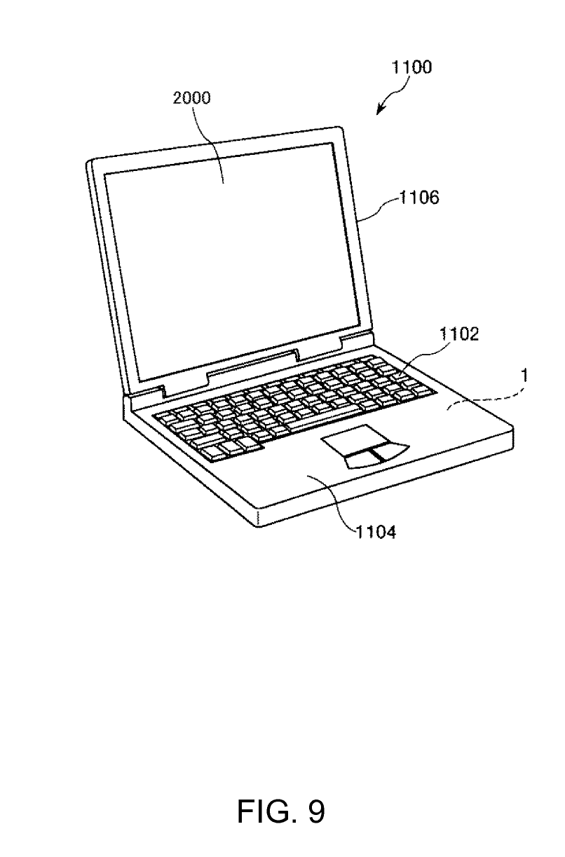

Next, an electronic apparatus (electronic apparatus according to the invention) including the MEMS structure according to the invention will be described in detail based on FIGS. 9 to 11.

FIG. 9 is a perspective view showing a configuration of a mobile (or notebook) personal computer as a first example of the electronic apparatus according to the invention. In the drawing, the personal computer 1100 is composed of a main body portion 1104 including a keyboard 1102, and a display unit 1106 including a display portion 2000. The display unit 1106 is rotatably supported to the main body portion 1104 via a hinge structure portion. Into the personal computer 1100, the MEMS structure 1 is built.

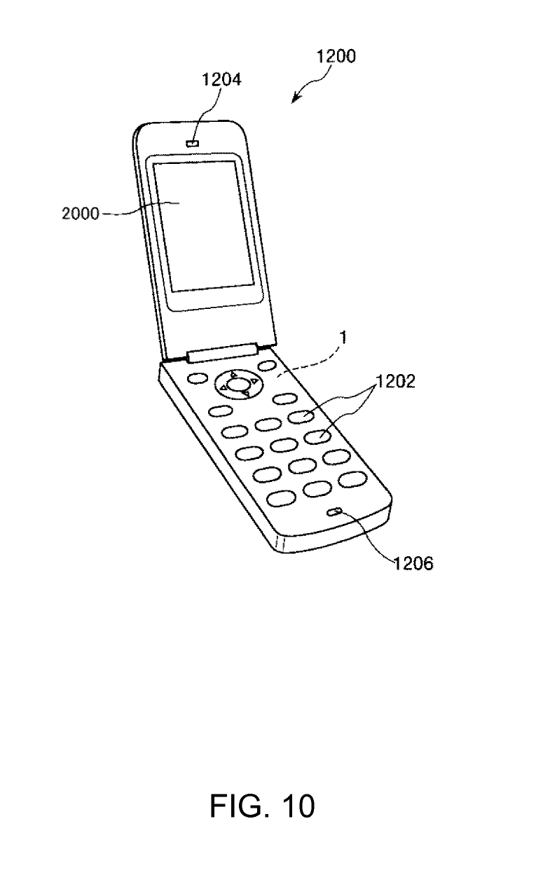

FIG. 10 is a perspective view showing a configuration of a mobile phone (including a PHS) as a second example of the electronic apparatus according to the invention. In the drawing, the mobile phone 1200 includes a plurality of operation buttons 1202, an earpiece 1204, and a mouthpiece 1206. The display portion 2000 is disposed between the operation buttons 1202 and the earpiece 1204. Into the mobile phone 1200, the MEMS structure 1 is built.

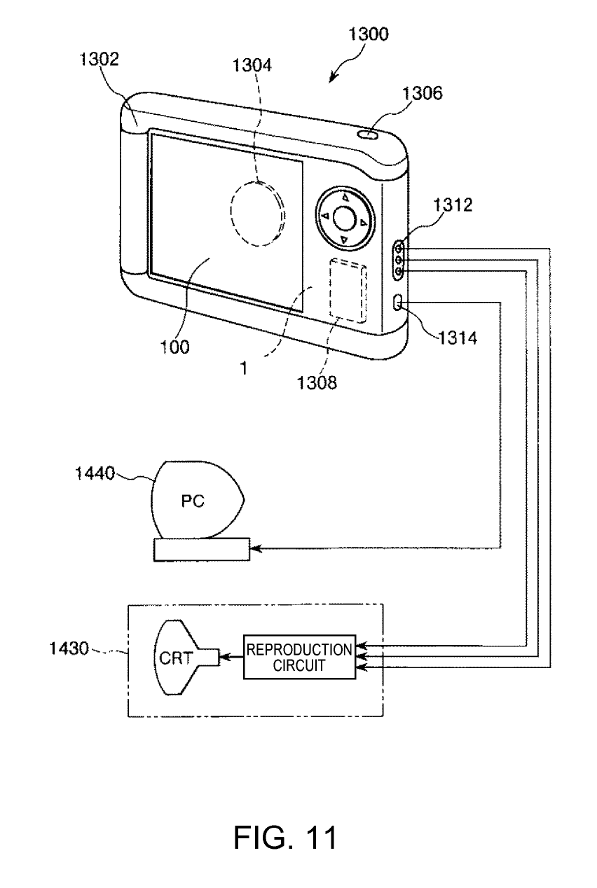

FIG. 11 is a perspective view showing a configuration of a digital still camera as a third example of the electronic apparatus according to the invention. In the drawing, connections with external apparatuses are also shown in a simplified manner. Here, usual cameras expose a silver halide photographic film with an optical image of a subject, whereas the digital still camera 1300 photoelectrically converts the optical image of the subject with an imaging device such as a CCD (Charge Coupled Device) to generate imaging signals (image signals).

A display portion is provided on a back surface of a case (body) 1302 in the digital still camera 1300 and configured to perform display based on the imaging signals generated by the CCD. The display portion functions as a finder that displays the subject as an electronic image. Moreover, on the front side (the rear side in the drawing) of the case 1302, a light receiving unit 1304 including an optical lens (imaging optical system) and the CCD is provided.

When a photographer confirms the subject image displayed on the display portion and presses down a shutter button 1306, imaging signals of the CCD at the time are transferred to and stored in a memory 1308. In the digital still camera 1300, a video signal output terminal 1312 and a data communication input/output terminal 1314 are provided on a side surface of the case 1302. Then, as shown in the drawing, a television monitor 1430 and a personal computer 1440 are connected as necessary to the video signal output terminal 1312 and the data communication input/output terminal 1314, respectively. Further, the imaging signals stored in the memory 1308 are output to the television monitor 1430 or the personal computer 1440 by a predetermined operation. Into the digital still camera 1300, the MEMS structure 1 is built.

The electronic apparatuses described above have excellent reliability.

In addition to the personal computer (mobile personal computer) shown in FIG. 9, the mobile phone shown in FIG. 10, and the digital still camera shown in FIG. 11, the electronic apparatus including the MEMS structure according to the invention can be applied to, for example, inkjet ejection apparatuses (e.g., inkjet printers), laptop personal computers, television sets, video camcorders, video tape recorders, car navigation systems, pagers, electronic notebooks (including those with communication function), electronic dictionaries, calculators, electronic gaming machines, word processors, workstations, videophones, surveillance television monitors, electronic binoculars, POS terminals, medical apparatuses (e.g., electronic thermometers, sphygmomanometers, blood glucose meters, electrocardiogram measuring systems, ultrasonic diagnosis apparatuses, and electronic endoscopes), fishfinders, various types of measuring instrument, indicators (e.g., indicators used in vehicles, aircraft, and ships), and flight simulators.

### 3. Moving Object

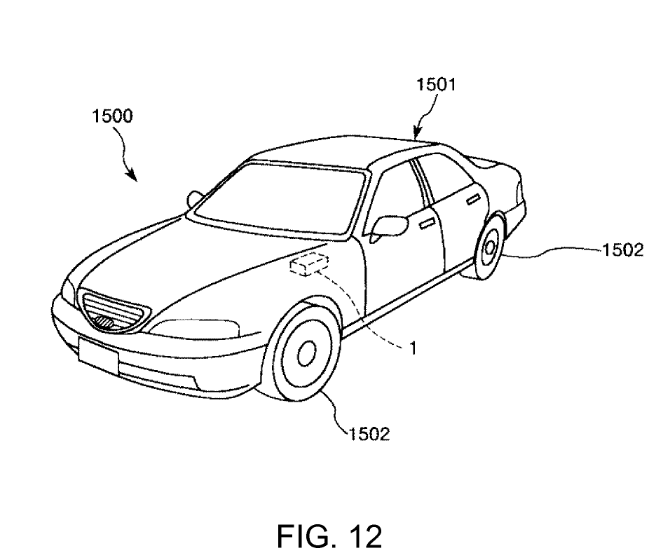

FIG. 12 is a perspective view showing a configuration of an automobile as an example of a moving object according to the invention.

In the drawing, a moving object 1500 includes a car body 1501 and four wheels 1502, and is configured to rotate the wheels 1502 with a power source (engine) (not shown) provided in the car body 1501. Into the moving object 1500, the MEMS structure 1 is built.

The moving object described above has excellent reliability. The moving object according to the invention is not limited to an automobile, and can be applied to, for example, various types of moving objects such as aircraft, ships, and motorcycles.

The MEMS structure, the electronic apparatus, and the moving object according to the invention have been described above based on the embodiments shown in the drawings, but the invention is not limited to the embodiments. The configuration of each part can be replaced with any configuration having a similar function. Moreover, any other configurations may be added to the embodiments.

In the embodiments, a description has been given of the case where the area of the fixed electrode in the plan view is larger than the area of the movable portion of the movable electrode. However, the area of the fixed electrode in the plan view may be the same as or smaller than the area of the movable portion of the movable electrode.

Moreover, in the embodiments, a description has been given of the configuration in which the movable portion of the vibrating element is supported in a cantilever fashion. However, the invention is not limited to the configuration, and the movable portion may be fixed at both ends. In this case, it is preferable to provide the projection at the central portion of the movable portion from the viewpoint of favorably reducing the sticking of the movable electrode to the fixed electrode.

Moreover, in the embodiments, a description has been given of an example in which the projection for reducing the sticking of the movable electrode to the fixed electrode is provided on the surface of the movable electrode on the fixed electrode side. However, the projection may be provided on a surface of the fixed electrode on the movable electrode side. In this case, the projection of the movable electrode may be omitted.

Moreover, in the embodiments, a description has been given of an example in which the projection for reducing the sticking of the movable electrode to the fixed electrode is provided at the portion on the free end side of the movable portion of the movable electrode. However, the projection may be provided on the fixed end side of the movable portion. In this case, it is preferable for the MEMS structure to be configured such that when the movable portion is displaced toward the fixed electrode side, the projection contacts the fixed electrode or other structures fixed to the substrate before the free end of the movable portion.

Moreover, in the embodiments, a description has been given of an example in which the projection for reducing the sticking of the movable electrode to the fixed electrode is disposed in the region in which the fixed electrode and the movable electrode overlap each other in the plan view. However, the projection may be disposed outside the region in which the fixed electrode and the movable electrode overlap each other. In this case, it is preferable for the MEMS structure to be configured such that when the movable portion is displaced toward the fixed electrode side, the projection contacts the fixed electrode or other structures fixed to the substrate before the free end of the movable portion.

Moreover, in the embodiments, a description has been given of an example in which the projection for reducing the sticking of the movable electrode to the fixed electrode is composed of a metal. However, for the material constituting the projection, a material different from that of the fixed electrode or the movable electrode may be appropriately selected from materials other than a metal, depending on the design of the movable electrode or the fixed electrode.

Moreover, in the embodiments, a description has been given of an example in which the metal portion including the projection for reducing the sticking of the movable electrode to the fixed electrode penetrates the movable portion. However, the invention is not limited to the example. For example, the metal portion may be locally fixed to the surface of the fixed electrode on the movable electrode side or the surface of the movable electrode on the fixed electrode side.

Moreover, in the embodiments, a description has been given of an example in which the fixed electrode and the movable electrode are formed by deposition. However, the invention is not limited to the example. For example, the fixed electrode or the movable electrode may be formed by etching a substrate.

The entire disclosure of Japanese Patent Application No. 2014-094456, filed May 1, 2014 is expressly incorporated by reference herein.

What is claimed is:

1. A MEMS structure comprising:
a substrate;
a fixed electrode disposed above the substrate;
a movable electrode including a movable portion disposed facing and spaced from the fixed electrode; and
a projection projecting from at least one of a surface of the fixed electrode on a side facing the movable portion and a surface of the movable portion on a side facing the fixed electrode, the projection including a material different from that of the fixed electrode or the movable portion.

2. The MEMS structure according to claim 1, wherein the projection includes a metal.

3. The MEMS structure according to claim 2, wherein the metal is tungsten.

4. The MEMS structure according to claim 2, further comprising a metal portion penetrating the movable portion and including the metal, wherein
a portion of the metal portion projecting from the movable portion constitutes the projection.

5. The MEMS structure according to claim 1, wherein the melting point of a material constituting the projection is higher than the melting point of a material constituting at least one of the movable electrode and the fixed electrode.

6. The MEMS structure according to claim 1, wherein the Young's modulus of a material constituting the projection is higher than the Young's modulus of a material constituting at least one of the movable electrode and the fixed electrode.

7. The MEMS structure according to claim 1, wherein a material constituting the projection has resistance to an etchant containing hydrofluoric acid.

8. The MEMS structure according to claim 1, wherein the number of the movable portions is more than one.

9. The MEMS structure according to claim 1, wherein the movable portion is supported in a cantilever fashion, and
the projection is disposed on a free end side of the movable portion.

10. The MEMS structure according to claim 1, wherein when viewed from a direction in which the fixed electrode and the movable portion are arranged in parallel, the projection is disposed in a region in which the fixed electrode and the movable portion overlap each other.

11. The MEMS structure according to claim 1, which is an electrostatically driven vibrator in which the movable portion is vibrated by generating a periodically changing electric field between the fixed electrode and the movable portion.

12. A method of manufacturing a MEMS structure, comprising:
preparing a substrate;
forming a fixed electrode forming film on the substrate;
forming a sacrificial layer on the fixed electrode forming film;
forming a movable electrode forming film on the sacrificial layer;
forming, from a metal, a projection projecting from a surface of the movable electrode forming film on the fixed electrode forming film side; and
etching the sacrificial layer.

13. An electronic apparatus comprising the MEMS structure according to claim 1.

14. A moving object comprising the MEMS structure according to claim 1.
